(19) United States
(12) Patent Application Publication
(10) Pub. No.: US 2015/0380219 A1
(43) Pub. Date: Dec. 31, 2015

(54) Mounting Stage and Plasma Processing Apparatus

(71) Applicant: Shibaura Mechatronics Corporation, Yokohama-shi (JP)

(72) Inventor: Kensuke Demura, Yokohama-shi (JP)

(73) Assignee: Shibaura Mechatronics Corporation, Yokohama-shi (JP)

(21) Appl. No.: 14/845,833

(22) Filed: Sep. 4, 2015

Related U.S. Application Data
(63) Continuation of application No. PCT/JP2014/058504, filed on Mar. 26, 2014.

(30) Foreign Application Priority Data
Mar. 28, 2013 (JP) 2013-069162

(51) Int. Cl. H01J 37/32

(52) U.S. Cl. CPC H01J 37/32715; H01J 37/32825; H01J 37/32229

(57) ABSTRACT

According to one embodiment, in a mounting stage for mounting a target substrate subjected to processing with reducing radicals, the mounting stage includes a mounting surface covered with the target substrate in plan view, a non-mounting surface adjacent to the mounting surface, and a mounting part configured to hold the target substrate. The mounting part is projected from the mounting surface and holds the target substrate so as to form a space between a back surface of the target substrate and the mounting surface during the processing, and surface of the mounting surface and the non-mounting surface are covered with a material suppressing deactivation of reducing radicals.

### CROSS-REFERENCE TO RELATED APPLICATIONS

This application is based upon and claims the benefit of priority from Japanese Patent Application No. 2013-069162, filed on Mar. 28, 2013, and PCT Patent Application PCT/JP2014/058504, filed on Mar. 26, 2014; the entire contents of which are incorporated herein by reference.

### FIELD

The invention relates to a mounting stage and a plasma processing apparatus.

### BACKGROUND

Ashing processing is performed to peel a resist formed on a target substrate such as a silicon wafer for semiconductor device manufacturing and a glass substrate for an exposure mask. One of the apparatuses for performing ashing processing is a plasma processing apparatus using a plasma.

Plasma processing such as ashing processing may include a chemical processing based primarily on radicals produced from a plasma. For instance, in what is generally called a remote plasma processing apparatus, the plasma generation region is isolated from the processing chamber. In the case of processing in the remote plasma processing apparatus, a plasma is generated in a discharge tube. Among the plasma products produced by the plasma, active species (radicals) having long lifetime are carried onto the target substrate surface to perform processing.

In such a plasma processing apparatus, as disclosed in JP H08-195343 a (Kokai), the surface of the members (e.g., the mounting stage for mounting a target substrate) in the processing chamber is previously covered with alumite (Al₂O₃) superior in gas corrosion resistance and heat resistance.

As disclosed in JP 2006-13190 A (Kokai), in recent ashing processing, a reducing gas such as hydrogen gas may be used as a processing gas with no damage to the foundation film of the resist.

However, if the surface of the members (e.g., the mounting stage for mounting a target substrate) in the processing chamber is covered with alumite, radicals carried to the processing chamber react with alumite in the processing chamber. This causes a problem of deactivating the radicals.

In particular, in the case of ashing processing with a hydrogen-containing gas, hydrogen radicals produced from the plasma of the hydrogen-containing gas are deactivated by reacting with oxygen contained in alumite. Thus, in the case of plasma processing with a reducing gas such as hydrogen, reducing radicals produced from the plasma of the reducing gas are deactivated by reacting with the member causing reduction reaction. This causes a problem of decreased ashing rate in the peripheral part of the target substrate. The peripheral part is a region close to the member causing reduction reaction such as alumite of the mounting stage surface.

### BRIEF DESCRIPTION OF DRAWINGS

FIG. 1 is a schematic sectional view for illustrating a plasma processing apparatus according to a first embodiment;

FIG. 2A and FIG. 2B are views of a target substrate W in viewing the cross-section;

FIG. 3A to FIG. 3C show the ashing rate distribution comparing the first embodiment with the conventional embodiment;

FIG. 4A to FIG. 4C are schematic sectional views for illustrating a plasma processing method according to a second embodiment; and

FIG. 5A to FIG. 5E are cross-sectional views of the target substrate W and the mounting stage 4.

### DETAILED DESCRIPTION

According to one embodiment, in a mounting stage for mounting a target substrate subjected to processing with reducing radicals, the mounting stage includes a mounting surface covered with the target substrate in plan view, a non-mounting surface adjacent to the mounting surface, and a mounting part configured to hold the target substrate. The mounting part is projected from the mounting surface and holds the target substrate so as to form a space between a back surface of the target substrate and the mounting surface during the processing, and surface of the mounting surface and the non-mounting surface are covered with a material suppressing deactivation of reducing radicals.

In the following, it is assumed that “ashing”, “resist peeling”, and “resist removal” are synonymous in the present embodiments. Furthermore, it is assumed that “active species” and “radical” are synonymous.

### First Embodiment

Embodiments will now be illustrated with reference to the drawings. In the drawings, similar components are labeled with like reference numerals, and the detailed description thereof is omitted appropriately.

The embodiment illustrates a plasma processing apparatus for peeling a resist formed on the target processing surface of a target substrate W such as a glass substrate.

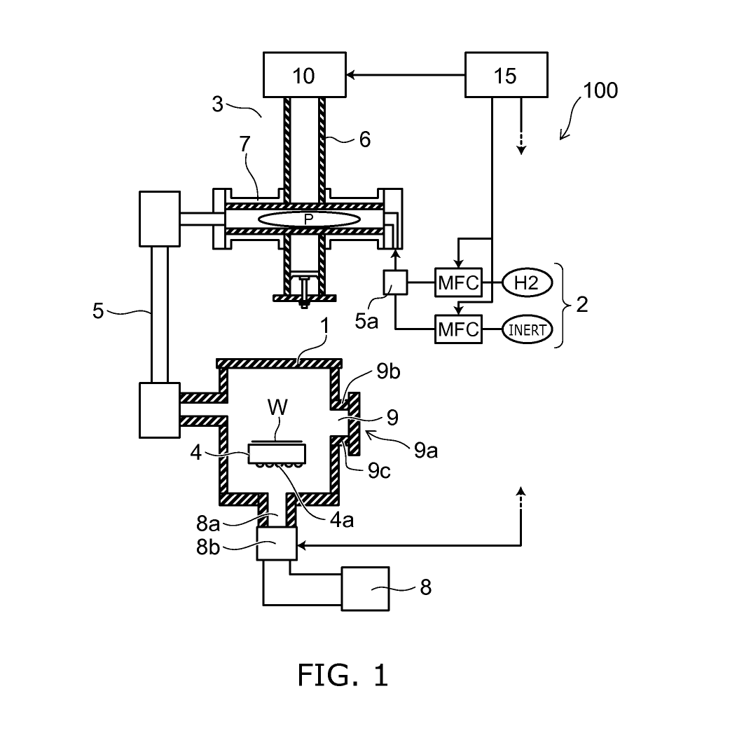

FIG. 1 is a schematic sectional view for illustrating a plasma processing apparatus 100 according to a first embodiment. The plasma processing apparatus 100 shown in FIG. 1 is a plasma processing apparatus in which the plasma generation region is isolated from a processing chamber 1. The plasma processing apparatus 100 is generally called a remote plasma processing apparatus.

The plasma processing apparatus 100 includes a processing chamber 1, a plasma generation section 3, and a decompression section 8. The plasma generation section 3 is provided with e.g. a discharge tube 7, a microwave generation section 10, a feed waveguide 6, and a gas supply section 2.

### (Processing Chamber 1)

The processing chamber 1 is a chamber sealed hermetically so as to be able to maintain a reduced pressure atmosphere. A target substrate W is mounted on a mounting stage 4 provided in the processing chamber 1. The target substrate W is subjected to ashing processing with plasma products produced in a plasma generated in the plasma generation region P. The mounting stage 4 includes a temperature control means 4a such as a heater. Thus, temperature control can be performed on the target substrate W. The mounting stage 4 will be described later.

(Carry in/Out Port 9)

A carry in/out port 9 for carrying the target substrate W into/out of the processing chamber 1 is provided in the sidewall of the processing chamber 1. The carry in/out port 9 is provided with a gate valve 9a. The gate valve 9a includes a gate 9b. The gate valve 9a opens/closes the carry in/out port 9 by opening/closing the gate 9b using a gate opening/closing mechanism (not shown). The gate 9b is provided with a sealing member 9c such as an O-ring. When the carry in/out port 9 is closed with the gate 9b, the sealing member 9c can seal the contact surface between the carry in/out port 9 and the gate 9b.

(Exhaust Port 8a)

An exhaust port 8a is provided near the bottom in the processing chamber 1. The exhaust port 8a is connected to the decompression section 8 through a pressure control section 8b. The decompression section 8 performs evacuation while controlling the pressure in the processing chamber 1 by the pressure control section 8b. Thus, the decompression section 8 reduces the pressure inside the processing chamber 1 to a prescribed pressure.

### (Discharge Tube 7, Gas Transport Section 5)

The discharge tube 7 includes a plasma generation region therein. The discharge tube 7 is connected to the processing chamber 1 through a gas transport section 5. The gas transport section 5 is connected to an opening, not shown, provided near the ceiling of the processing chamber 1. Plasma products produced in the plasma generation region P can reach the major surface of the target substrate W through this gas transport section 5.

### (Gas Supply Section 2)

The gas supply section 2 introduces a prescribed amount of processing gas G to the plasma generation region P inside the discharge tube 7 through a gas mixing section 5a. The gas mixing section 5a mixes two or more kinds of processing gases at a prescribed ratio. This processing gas G is excited in the plasma generation region P to produce plasma products. The processing gas G can be a mixed gas of a hydrogen-containing gas and an inert gas. The inert gas can be nitrogen, helium, or argon. The processing gas G may be hydrogen gas alone. In this case, the gas mixing section 5a may be omitted. Plasma products such as hydrogen radicals are produced in the case where the processing gas G is a hydrogen-containing gas.

### (Microwave Generation Section 10)

The microwave generation section 10 causes oscillation of a microwave M with a prescribed power (e.g., 2.45 GHz) and emits it to the feed waveguide 6.

### (Feed Waveguide 6)

The feed waveguide 6 propagates the microwave M emitted from the microwave generation section 10. The feed waveguide 6 introduces the microwave M to the plasma generation region P inside the discharge tube 7.

A plasma of the processing gas G is formed in the plasma generation region P with the energy applied by the introduced microwave M. Active species such as radicals contained in the plasma are supplied onto the target substrate W in the processing chamber 1 through the gas transport section 5. Thus, the resist is subjected to ashing processing.

Here, the surface of the member exposed to hydrogen radicals during migration from the plasma generation region P to the surface of the target substrate W may be formed from an oxygen-containing material such as quartz (SiO₂) and alumite (Al₂O₃). In this case, reduction reaction occurs when the hydrogen radicals reach the surface of the member. That is, hydrogen radicals contributing to the processing of the target substrate W are consumed and deactivated by reduction reaction with the surface of the member exposed to the hydrogen radicals during migration from the plasma generation region P to the surface of the target substrate W. As a result, the processing efficiency of the target substrate W is decreased. This also applies to the case where the surface of the member includes nitride.

Thus, the surface of the member exposed to hydrogen radicals during migration from the plasma generation region P to the surface of the target substrate W is covered with silicon (Si). Silicon (Si) contains no oxygen. Thus, silicon (Si) causes no reduction reaction with hydrogen radicals. This can prevent deactivation of radicals at the member surface. As a result, the decrease of the processing efficiency of the target substrate W can be prevented.

Here, in the following description, the mounting stage 4 for mounting the target substrate W is further taken as an example of the member exposed to hydrogen radicals during migration from the plasma generation region P to the surface of the target substrate W.

### (Mounting Stage 4)

The surface of the mounting stage 4 may be formed from an oxygen-containing material such as quartz (SiO₂) and alumite (Al₂O₃). In this case, reduction reaction occurs when hydrogen radicals reach the surface of the member.

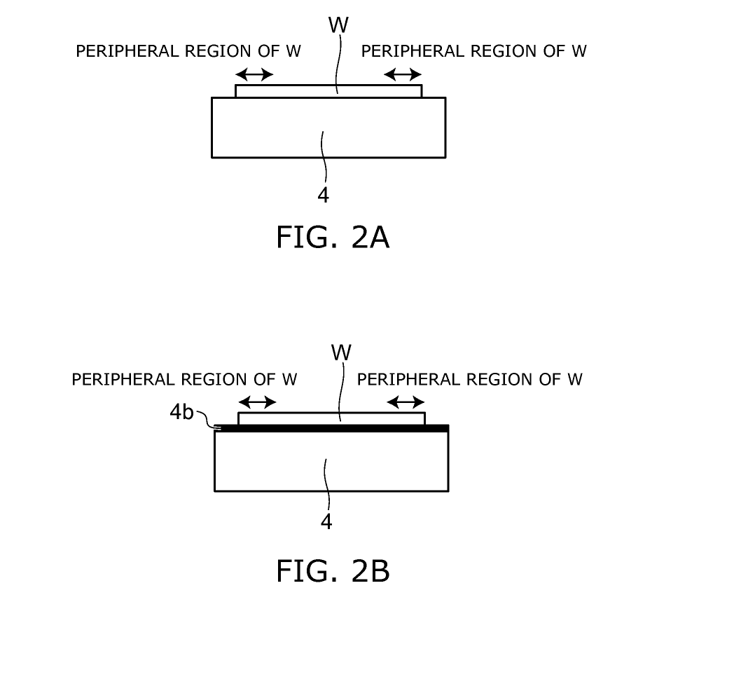

In particular, as shown in FIG. 2A, the processing rate decreases in the peripheral portion of the target substrate W close to the surface of the mounting stage 4. As a result, the processing uniformity of the target substrate W decreases.

Thus, as shown in FIG. 2B, in the embodiment, a susceptor 4b is mounted on the upper surface of the mounting stage 4 (the surface on the side on which the target substrate W is mounted). The surface of the susceptor 4b is covered with silicon (Si).

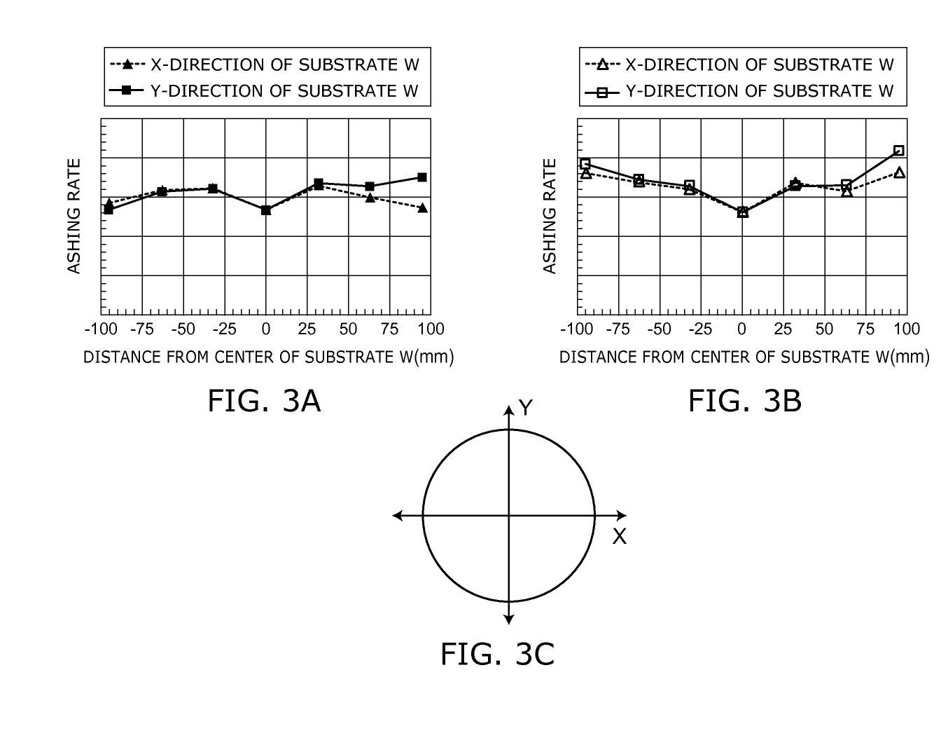

FIGS. 3A to 3C show the resist peeling rate (ashing rate) distribution comparing the embodiment with the conventional mode. In FIGS. 3A and 3B, a silicon substrate (target substrate W) with a resist layer formed thereon was subjected to ashing processing for peeling the resist layer. FIG. 3A shows the ashing rate in the conventional mode. FIG. 3B shows the ashing rate of the embodiment. FIG. 3C shows the X-direction and the Y-direction on the major surface of the target substrate W.

In the embodiment (FIG. 3B), as described above, a susceptor 4b covered with silicon (Si) is mounted on the upper surface of the mounting stage 4. The target substrate W is mounted thereon and subjected to ashing processing. In the conventional mode (FIG. 3A), the mounting stage 4 is applied with surface treatment of alumite (Al₂O₃). The target substrate W is mounted thereon and subjected to ashing processing.

In the embodiment, the susceptor 4b covered with silicon (Si) is mounted on the mounting stage 4. Obviously, this prevents the decrease of resist peeling rate at the periphery of the target substrate W compared with the conventional mode (FIG. 3A). That is, the embodiment can suppress deactivation of hydrogen radicals in the peripheral region of the target substrate W. As a result, the processing uniformity of the target substrate W can be improved.

In view of suppressing deactivation of hydrogen radicals by suppressing reduction reaction with the surface of the member, the surface of the member only needs to be formed from a material other than oxide. However, in view of contamination of the target substrate W, the material covering the susceptor 4b is preferably a material constituting the target substrate W. In the case where the target substrate W is made of e.g. quartz (SiO₂) or silicon (Si), the material of the surface of the member is preferably a material containing silicon (Si). Furthermore, as described above, silicon (Si) can suppress deactivation of hydrogen radicals and prevent contamination of the target substrate W.

As is clear from FIG. 3A, it is the peripheral part of the target substrate W that is affected by the decrease of ashing rate due to deactivation of hydrogen radicals. Thus, the susceptor 4b may be shaped like a hollow member covering the exposed portion of the mounting surface of the mounting stage 4 (the portion on which the target substrate W is not located as viewed from directly above the mounting stage 4) and holding only the peripheral part of the target substrate W. For instance, the susceptor 4b may be a ring-shaped member. In this case, the in-plane temperature distribution in the processing region (e.g., device formation region) of the target substrate W is preferably made uniform at the time of heating. To this end, the width of the ring may be set so that the portion holding the target substrate W lies outside the processing region of the target substrate W.

According to the embodiment, the mounting stage 4 for mounting the target substrate may be formed from an oxygen-containing material such as quartz (SiO₂) and alumite (Al₂O₃). In this case, the embodiment can prevent reduction reaction when hydrogen radicals reach the surface of the member. That is, a susceptor 4b with the surface covered with silicon (Si) is provided on the upper surface of the mounting stage 4 (the surface on the side on which the target substrate W is mounted). This can suppress that radicals produced in the plasma generation region P are deactivated at the surface of the mounting stage 4 formed from the oxygen-containing material. As a result, the decrease of ashing rate in the peripheral region of the target substrate W close to the mounting stage 4 can be suppressed. This can improve the processing uniformity of the target substrate W.

### Second Embodiment

### Plasma Processing Method

Embodiments will now be illustrated with reference to the drawings. In the drawings, similar components are labeled with like reference numerals, and the detailed description thereof is omitted appropriately.

The embodiment illustrates a plasma processing method for peeling a resist formed on the target processing surface of a glass substrate (base body). Furthermore, the embodiment describes a resist peeling processing in a series of steps for manufacturing an EUV mask blank.

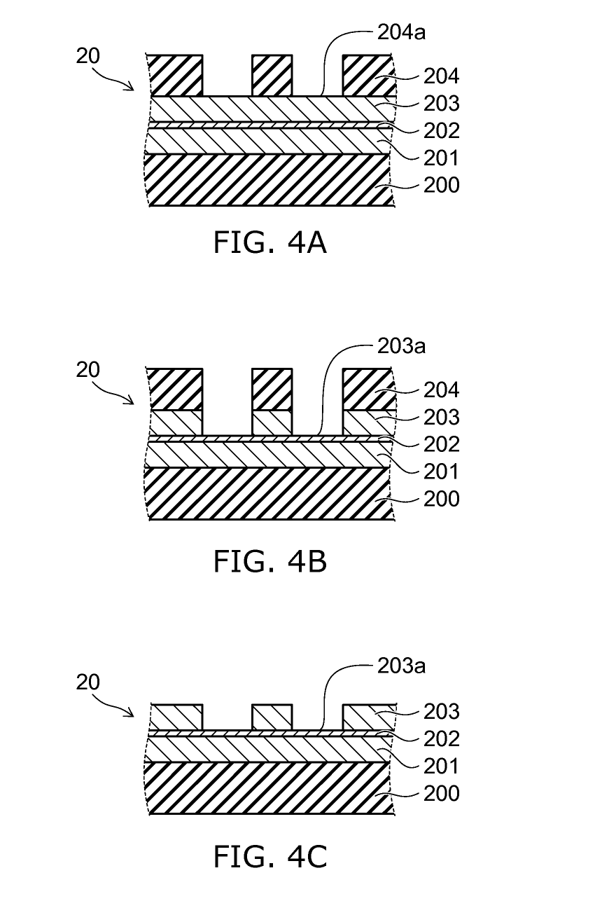

FIGS. 4A to 4C are schematic sectional views for illustrating a plasma processing method according to a second embodiment.

First, an EUV mask substrate (target substrate) W is prepared. In the EUV mask substrate, a reflective layer 201, a protective layer 202, an absorber layer 203, and a resist 204 are stacked in this order on a base body 200.

The base body 200 is composed of a material such as quartz. The reflective layer 201 can be a multilayer reflective film. In the reflective layer 201, 40 layers of materials having greatly different refractive indices such as molybdenum film and silicon film are alternately stacked to enhance light reflectance of the layer surface irradiated with EUV light. The protective layer 202 is provided to prevent damage to the reflective layer 201 at the time of plasma etching of the absorber layer 203 as described above. The protective layer 202 can include ruthenium (Ru) or chromium nitride (CrN). The absorber layer 203 can be made of a material having high absorption coefficient for EUV light, such as a material composed primarily of e.g. chromium (Cr) or tantalum (Ta). The absorber layer 203 may be formed by stacking two or more layers having different reflectances for irradiation with EUV light.

As shown in FIG. 4A, a patterned resist 204 serving as an etching mask is formed on the surface of the absorber layer 203. The patterning of the resist 204 is performed by existing methods. At this time, the absorber layer 203 is exposed in the opening 204a of the resist.

Next, as shown in FIG. 4B, a pattern corresponding to the opening 204a of the resist is formed in the absorber layer 203 by a first etching processing. The first etching processing can be performed by plasma processing. The processing gas used in this processing can be a gas likely to react with the material of the absorber layer 203. For instance, the processing gas can be a chlorine-based gas such as Cl₂, HCl, and CCl₄, or a mixed gas with another gas.

Thus, a pattern is formed in the absorber layer 203 by the first etching processing. At this time, the surface of the protective layer 202 is exposed in the opening 203a of the absorber layer.

Then, as shown in FIG. 4C, the resist 204 is removed.

At this time, the resist 204 is removed by the plasma of a mixed gas of hydrogen and an inert gas.

Here, the mounting stage 4 for mounting the target substrate may be formed from an oxygen-containing material such as quartz (SiO₂) and alumite (Al₂O₃). However, use of the plasma processing apparatus of the first embodiment can prevent reduction reaction when hydrogen radicals reach the surface of the member. That is, a susceptor 4b covered with silicon (Si) is provided on the upper surface of the mounting stage 4 (the surface on the side on which the target substrate W is mounted). This can suppress that radicals produced in the plasma generation region P are deactivated at the surface of the mounting stage 4 formed from the oxygen-containing material. As a result, the decrease of ashing rate in the peripheral region of the target substrate W close to the mounting stage 4 can be suppressed. This can improve the processing uniformity of the target substrate W.

At the time of resist removal, temperature control may be performed by the temperature control means 4a provided in the mounting stage 4. This can suppress diffusion of the molybdenum layer.

After removing the resist 204, a resist can be applied again onto the protective layer 202 as necessary and patterned. This resist can be used as a mask to perform etching processing on the protective layer 202 and the reflective layer 201.

As described above, the resist 204 formed on the target surface of the base body 200 can be peeled.

The first and second embodiments have been illustrated above. However, the invention is not limited to the above description.

Those skilled in the art can appropriately modify the above embodiments by addition, deletion, or design change of components, or by addition, omission, or condition change of steps. Such modifications are also encompassed within the scope of the invention as long as they include the features of the invention.

For instance, in the above description, a plasma processing apparatus of the remote plasma type is taken as an example of the plasma processing apparatus of the embodiments. However, the embodiments are also applicable to plasma processing apparatuses of other modes. For instance, the embodiments are also applicable to the downflow type in which the plasma generation region and the reaction chamber in which the target substrate W is mounted are provided in the same processing chamber.

In the above first and second embodiments, the mounting stage 4 formed from an oxygen-containing material such as quartz (SiO₂) and alumite (Al₂O₃) is taken as an example of the member exposed to hydrogen radicals. In this case, the susceptor 4b with the surface covered with silicon (Si) is provided on the upper surface of the mounting stage 4 (the surface on the side on which the target substrate W is mounted). This suppresses that radicals produced in the plasma generation region P are deactivated at the surface of the mounting stage 4 formed from the oxygen-containing material. However, it is only necessary to cover the surface of the mounting stage 4 with silicon (Si). Thus, the surface of the mounting stage 4 may be covered with a silicon film instead of the susceptor 4b. However, the susceptor 4b is detachable from the mounting stage 4. Thus, the susceptor 4b can be detached and cleaned. Accordingly, use of the susceptor 4b improves maintenance capability.

The embodiments may be applied to a member exposed to hydrogen radicals during migration from the plasma generation region P to the surface of the target substrate W instead of the mounting stage 4 or in conjunction with the mounting stage 4. This member exposed to hydrogen radicals during migration from the plasma generation region P to the surface of the target substrate W can be e.g. an inner wall surface or a straightener (not shown) for straightening a gas flow in the processing chamber 1, or the inner wall surface of the gas transport section 5.

The surface of the member exposed to hydrogen radicals during migration from the plasma generation region P to the surface of the target substrate W may be formed from an oxygen-containing material such as quartz (SiO₂) and alumite (Al₂O₃). Even in this case, the embodiments can prevent reduction reaction when the hydrogen radicals reach the surface of the member. That is, the embodiments can prevent that radicals contributing to the processing of the target substrate W are consumed and deactivated by reduction reaction with the member surface exposed to the hydrogen radicals during migration from the plasma generation region P to the surface of the target substrate W. This can prevent the decrease of the processing efficiency of the target substrate W.

In the above first and second embodiments, various members are covered with silicon (Si). However, only the member surface needs to be made of silicon (Si). Thus, the member itself may be made of silicon (Si).

Furthermore, in the above description, resist peeling processing is taken as an example of the plasma processing method of the embodiments. However, the embodiments are also applicable to plasma processing methods of other modes such as etching processing for processing with hydrogen radicals.

In the above first and second embodiments, the processing gas G is a hydrogen-containing gas. However, the embodiments are also applicable to processing using reducing radicals produced by other reducing gases.

### Third Embodiment

The embodiment relates to e.g. a mounting stage used in a plasma processing apparatus.

The plasma processing apparatus 100 shown in FIG. 1 is used also in the embodiment. The plasma processing apparatus 100 is a plasma processing apparatus in which the plasma generation region is isolated from a processing chamber 1.

A target substrate W is mounted on a mounting stage 4 provided in the processing chamber 1. The target substrate W is subjected to plasma processing with plasma products such as active species (radicals) produced in a plasma generated in the plasma generation region P.

Also in the embodiment, the target substrate W is subjected to plasma processing with reducing radicals such as hydrogen radicals.

As in the above first and second embodiments, the surface of the member exposed to reducing radicals may be formed from an oxygen-containing material such as quartz (SiO₂) and alumite (Al₂O₃). In this case, reduction reaction occurs when the reducing radicals reach the surface of the member. That is, radicals contributing to the processing of the target substrate W are consumed and deactivated by reduction reaction with the surface of the member in the processing chamber 1. As a result, the processing efficiency of the target substrate W is decreased. This also applies to the case where the surface of the member includes nitride.

Thus, the surface of the member exposed to reducing radicals is covered with a material not causing reduction reaction with the reducing radicals. The material not causing reduction reaction can be e.g. silicon (Si) or a solid metal material (such as Al, Pt, and Au). These do not contain materials causing reduction reaction such as oxide and nitride. Thus, they do not cause reduction reaction with reducing radicals. This can prevent deactivation of radicals at the member surface. As a result, the decrease of the processing efficiency of the target substrate W can be prevented.

The mounting stage 4 is a member for mounting the target substrate W. The mounting stage 4 is shaped like e.g. a cylinder.

Here, in plan view of this mounting stage 4 on which the target substrate W is mounted, the portion covered with the target substrate W is referred to as a mounting surface. The portion not covered with the target substrate W is referred to as a non-mounting surface. Both the surfaces are collectively referred to as an upper surface. The non-mounting surface is provided adjacent to the mounting surface. The non-mounting surface may be made of the same member as the mounting surface, or may be composed of a different member.

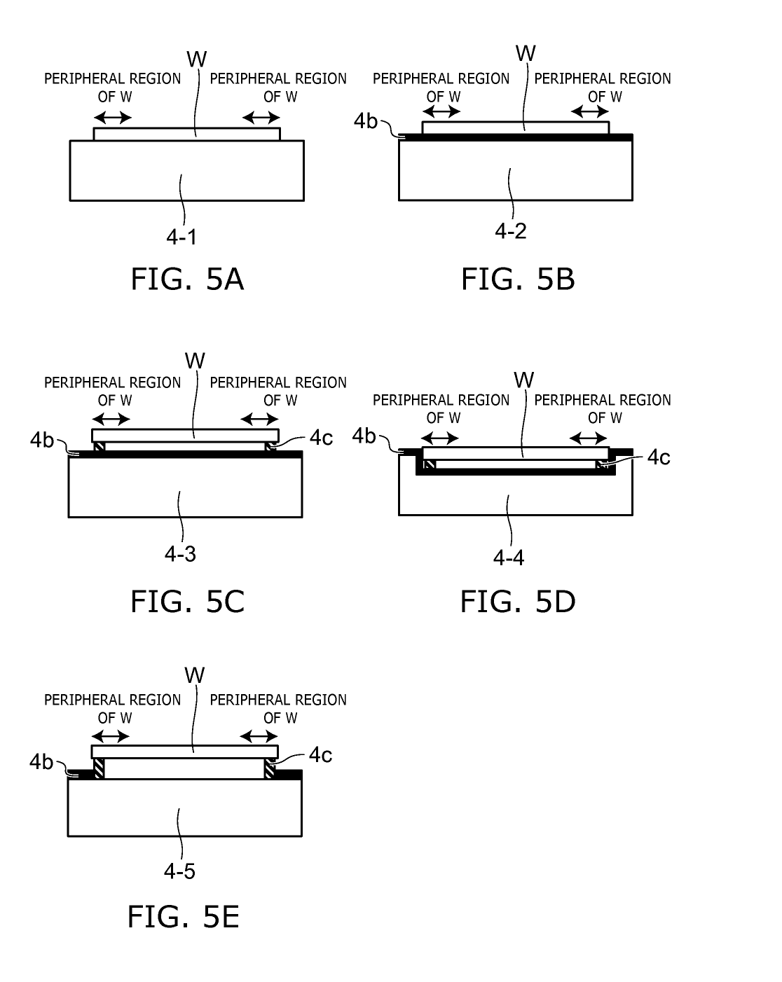

FIG. 5A shows a mounting stage 4-1 in a comparative example. The upper surface (mounting surface and non-mounting surface) of the mounting stage 4-1 is applied with surface treatment of alumite (Al₂O₃).

In FIG. 5A, the upper surface of the mounting stage 4-1 is formed from a material causing reduction reaction. In this case, radicals are consumed by reduction reaction with the non-mounting surface exposed outside the target substrate W. As a result, the amount of radicals contributing to processing decreases in the peripheral region of the target substrate W close to the non-mounting surface. This decreases the ashing rate. As a result, the processing uniformity of the target substrate W decreases.

FIGS. 5B to 5E show mounting stages 4-2-4-5 in the embodiment.

In FIG. 5B, the target substrate W is mounted so that the mounting surface of the mounting stage 4-2 is brought into contact with the back surface of the target substrate W.

In FIGS. 5C to 5E, the target substrate W is mounted with a spacing provided between the mounting surface of the mounting stage 4-3-4-5 and the back surface of the target substrate W.

The target substrate W may be a quartz substrate used as a photomask. In this case, when the target substrate W is mounted on the mounting stage 4, flaws, soil and the like may be attached to the back surface of the product region in the target substrate W. This causes deterioration of transparency of the target substrate W.

Thus, the target substrate W is mounted so that the back surface of its product region (e.g., central part) is spaced from the mounting surface of the mounting stage 4. For instance, the back surface of the non-product region (e.g., circumferential part) of the target substrate W is held by a mounting part 4c projected from the mounting surface of the mounting stage 4. This mounting part 4c is a rod-shaped member such as a pin. The mounting part 4c is configured so that the target substrate W can be held at its tip part.

This mounting part 4c is connected to an elevation means including a driving source. By a raising/lowering action, the mounting part 4c can adjust the spacing between the back surface of the target substrate W and the mounting surface of the mounting stage 4. For instance, at the time of ashing, the spacing is adjusted so that the temperature control means 4a of the mounting stage 4 can perform temperature control of the target substrate W by radiation heat. At the time of carry in/out of the target substrate W, the spacing is adjusted so as to admit the transfer hand of a transfer robot.

As shown in FIGS. 5B to 5E, a susceptor 4b is mounted on the upper surface of the mounting stages 4-2-4-5 in the embodiment. The surface of the susceptor 4b is covered with a material not causing reduction reaction. In the embodiment, the material not causing reduction reaction is silicon (Si). In the embodiment, the reducing radicals are hydrogen radicals.

According to the embodiment, even if a gas including reducing radicals impinges on the non-mounting surface, the non-mounting surface is formed from a material not causing reduction reaction. This can prevent deactivation of the reducing radicals.

Here, the ashing rate of ashing processing based primarily on radicals is affected by the amount of radicals produced in the plasma generation region P and included in the gas reaching the target substrate W.

The radicals have no directionality. Thus, the radicals are guided by the flow of the gas and reach the target substrate W.

This gas is supplied from the opening of the gas transport section 5 provided near the ceiling of the processing chamber 1. The gas is exhausted from the exhaust port 8a provided near the bottom of the processing chamber 1. This forms a downflow flowing from top to bottom in the processing chamber 1. However, part of the gas impinges on members in the processing chamber 1 to cause convection. This may cause a gas flow from bottom to top.

Thus, even if the gas including radicals impinges on the non-mounting surface of the mounting stage 4 (4-2-4-5), the gas causes convection and reaches the processing surface of the target substrate W. The radicals included in the gas can react with the processing surface and perform processing. That is, in the mounting stage 4-1 of the comparative example, the non-mounting surface is formed from a material causing reduction reaction. Then, reducing radicals are consumed at the non-mounting surface of the mounting stage 4-1. However, in the embodiment, the reducing radicals are not consumed, but reach the upper surface of the target substrate W by the convection of the gas. Thus, the reducing radicals can contribute to the processing of the target substrate W. This can increase the amount of radicals contributing to processing and improve the ashing rate of the target substrate W.

Furthermore, in the embodiment, the area of the non-mounting surface of the mounting stage 4 is made larger than the area of the target substrate W (the area of the mounting surface). For instance, the target substrate W is a disk having a diameter of 200 mm. Then, the upper surface of the mounting stage 4 can be shaped like a circle having a diameter of 300 mm. This can sufficiently enlarge the non-mounting surface. Thus, the gas including radicals can efficiently cause convection by impinging on the non-mounting surface. That is, if the area of the upper surface of the mounting stage 4 is nearly equal to that of the target substrate (if the non-mounting surface is nearly zero), the gas including radicals may be exhausted by the decompression section 8. However, in the embodiment, the non-mounting surface is large enough to cause convection. Thus, the gas impinges on the non-mounting surface and can be carried to the target substrate W. As a result, the amount of radicals contributing to processing can be increased. This can improve the ashing rate of the target substrate W.

Furthermore, in the embodiment, the non-mounting surface of the mounting stages 4-2-4-5 covered with the material not causing reduction reaction with reducing radicals is preferably located below the processing surface of the target substrate W.

Consider the case where the non-mounting surface is formed from a material not causing reduction reaction. Even in this case, if the non-mounting surface is located above the processing surface of the target substrate W, the gas including radicals impinges on the non-mounting surface earlier than on the processing surface. This may deactivate radicals by reaction between the radicals. However, in the mounting stages 4-2-4-5 of the embodiment, the non-mounting surface is located below the processing surface of the target substrate W. This can prevent deactivation of radicals due to impingement on the non-mounting surface before the gas including radicals reaches the target substrate W. Thus, the amount of radicals contributing to processing can be increased, and the ashing rate of the target substrate W can be improved.

The effect of the embodiment can be achieved by covering at least the exposed portion of the mounting surface of the mounting stage 4 (non-mounting surface) with a material not causing reduction reaction with reducing radicals, as in the mounting stage 4-5. However, as in the mounting stages 4-2-4-4, it is preferable to cover the surface with a material not causing reduction reaction with reducing radicals not only on the exposed portion of the mounting surface of the mounting stage 4 (non-mounting surface), but also on the portion covered with the target substrate W (mounting surface). As described above, the back surface of the target substrate W may be spaced from the mounting surface. In this case, organic substances such as the resist attached to the back surface of the target substrate W can also be removed by radicals passing through this spacing.

As described with reference to FIGS. 3A to 3C, in the embodiment, the susceptor 4b covered with silicon (Si) is mounted on the mounting stage 4. Obviously, this prevents the decrease of ashing rate at the periphery of the target substrate W compared with the conventional mode (FIG. 3A). That is, the embodiment can suppress deactivation of reducing radicals in the peripheral region of the target substrate W. As a result, the processing uniformity of the target substrate W can be improved.

In the above, the first to third embodiments are illustrated. However, the invention is not limited to these descriptions.

For instance, in the above description, a plasma processing apparatus of the remote plasma type is taken as an example of the plasma processing apparatus of the embodiments. However, the embodiments are also applicable to plasma processing apparatuses of other modes for processing using radicals. For instance, the embodiments are also applicable to the downflow type in which the plasma generation region and the reaction chamber in which the target substrate W is mounted are provided in the same processing chamber. Furthermore, the embodiments are also applicable to e.g. a surface wave plasma (SWP) processing apparatus and an inductively coupled plasma (ICP) processing apparatus.

In the above embodiments, for instance, the susceptor 4b with the surface covered with silicon (Si) is provided on the upper surface of the mounting stage 4 (the surface on the side on which the target substrate W is mounted). However, it is only necessary to cover the surface of the mounting stage 4 with silicon (Si). Thus, the surface of the mounting stage 4 may be covered with a silicon film instead of the susceptor 4b. However, the susceptor 4b is detachable from the mounting stage 4. Thus, the susceptor 4b can be detached and cleaned. Accordingly, use of the susceptor 4b improves maintenance capability. Here, in the case of mounting the susceptor 4b on the upper surface of the mounting stage 4, the “non-mounting surface” in the above embodiments is made of the surface of the susceptor 4b. The “non-mounting surface” in the case of covering the surface of the mounting stage 4 with a silicon film is made of the surface of the mounting stage 4.

In conjunction with the mounting stage 4, the surface of the member exposed to reducing radicals during migration from the plasma generation region P to the surface of the target substrate W may be covered with a material not causing reduction reaction with the radicals. This member exposed to reducing radicals during migration from the plasma generation region P to the surface of the target substrate W can be e.g. an inner wall surface or a straightener (not shown) for straightening a gas flow in the processing chamber 1, or the inner wall surface of the gas transport section 5.

Then, the embodiments can prevent that radicals contributing to the processing of the target substrate W are consumed and deactivated by reduction reaction with the member surface exposed to the reducing radicals during migration from the plasma generation region P to the surface of the target substrate W. This can prevent the decrease of the processing efficiency of the target substrate W.

In the above embodiments, various members are covered with silicon (Si). However, only the member surface needs to be made of silicon (Si). Thus, the member itself may be made of silicon (Si).

In the description of the above embodiments, silicon (Si) is taken as an example of the material not causing reduction reaction with radicals. However, in view of suppressing deactivation of reducing radicals by suppressing reduction reaction with the surface of the member, the surface of the member only needs to be formed from a material other than oxide and nitride. The material can be e.g. silicon (Si) or a solid metal material (such as Al, Pt, and Au).

However, in view of contamination of the target substrate W, the material covering the susceptor 4b is preferably a material constituting the target substrate W. Furthermore, the material covering the susceptor 4b is preferably a material less prone to oxidation when the processing chamber 1 is exposed to the atmosphere. For instance, in the case where the target substrate W is made of e.g. quartz (SiO₂) or silicon (Si), the material of the surface of the member can be silicon (Si).

Furthermore, in the above description, resist peeling processing is taken as an example of the plasma processing method of the embodiments. However, the embodiments are also applicable to plasma processing methods of other modes such as etching processing for processing with reducing radicals and plasma cleaning of organic substances attached to a photomask used for light exposure.

Furthermore, in the above description, ashing of a quartz substrate used as a photomask is taken as an example of the plasma processing method of the embodiments. However, the target substrate W may be a semiconductor wafer, and organic substances attached to the back surface may be removed in conjunction with removing the resist on the front surface. Also in this case, resist peeling processing can be performed while holding the target substrate W by the mounting part.

The shape in plan view of the target substrate W, the mounting stage 4, and the susceptor 4b of the embodiments may be e.g. a disk or a rectangle.

Each element included in each example described above can be combined to the extent possible, and these combinations are also encompassed within the scope of the invention as long as they include the features of the invention.

What is claimed is:

1. A mounting stage for mounting a target substrate subjected to processing with reducing radicals,
the mounting stage comprising a mounting surface covered with the target substrate, a non-mounting surface adjacent to the mounting surface, and a mounting part configured to hold the target substrate in plan view,
the mounting part being projected from the mounting surface and holding the target substrate so as to form a spacing between a back surface of the target substrate and the mounting surface during the processing, and
surface of the mounting surface and the non-mounting surface being covered with a material suppressing deactivation of reducing radicals.

2. The stage according to claim 1, wherein the material is silicon (Si).

3. The stage according to claim 1, wherein the reducing radicals are hydrogen radicals.

4. The stage according to claim 1, wherein the target substrate is a quartz substrate.

5. The stage according to claim 1, wherein area of the non-mounting surface is larger than area of the target substrate.

6. The stage according to claim 1, wherein the non-mounting surface includes a surface of a susceptor detachable from the mounting stage.

7. A plasma processing apparatus comprising:
a processing chamber capable of maintaining an atmosphere with pressure lower than atmospheric pressure;
a mounting stage provided in the processing chamber and configured to mount a target substrate; and
a plasma generation section configured to produce reducing radicals for processing the target substrate,
the mounting stage being based on a mounting stage for mounting a target substrate subjected to processing with reducing radicals,
the mounting stage comprising a mounting surface covered with the target substrate, a non-mounting surface adjacent to the mounting surface, and a mounting part configured to hold the target substrate in plan view,
the mounting part being projected from the mounting surface and holding the target substrate so as to form a spacing between a back surface of the target substrate and the mounting surface during the processing, and
surface of the mounting surface and the non-mounting surface being covered with a material suppressing deactivation of reducing radicals.

8. The apparatus according to claim 7, wherein the plasma generation section includes:
a discharge tube connected to the processing chamber through a gas transport section and including a plasma generation region therein;
a gas introduction device configured to introduce a hydrogen-containing gas to the plasma generation region; and
a microwave introduction device configured to introduce a microwave to the plasma generation region.

9. The apparatus according to claim 7, wherein the non-mounting surface of the mounting stage is located below a processing surface of the target substrate when the target substrate is mounted.
